(19) United States
(12) Patent Application Publication
(10) Pub. No.: US 2025/0289314 A1
(43) Pub. Date: Sep. 18, 2025

(54) MONITORING METHOD

(71) Applicants: ELDOR CORPORATION S.P.A., Orsenigo (Como) (IT); DR. ING. H.C. F. PORSCHE AG, Stuttgart (DE)

(72) Inventors: Francesco BERTINO, Orsenigo (Como) (IT); Stefano DATTILO; Paolo LISANTI, Orsenigo (Como) (IT); Pasquale FORTE, Orsenigo (Como) (IT)

(21) Appl. No.: 18/861,147

(22) PCT Filed: Apr. 27, 2023
(86) PCT No.: PCT/IB2023/054355

§ 371 Date: Oct. 28, 2024

(30) Foreign Application Priority Data
Apr. 29, 2022 (IT) 102022000008600

(51) Int. Cl. B60L 3/00; B60L 3/04; G01R 31/52

(52) U.S. Cl. CPC B60L 3/0069; B60L 3/04; G01R 31/52; B60L 2250/10

(57) ABSTRACT

This invention relates to a method for monitoring a voltage value on a vehicle frame when connected to a power grid. The method is performed by acquiring signals representing the voltage values between respective terminals connected to the nodes of the power grid and the vehicle frame. The signals are filtered so as to split their components at the grid frequency of the power grid with respect to those at lower or higher frequency ranges. The components in the three ranges identified are analysed separately and if one of their representative values exceeds respective, predetermined threshold values, a warning signal is generated.

This invention relates to the technical field of safety procedures.

In particular, this invention relates to a monitoring method advantageously applicable in the automotive field.

This method involves monitoring the possible electrical potential value present between the vehicle frame and the grounding in such a way as to enable a user to be alerted if said value reaches levels and/or characteristics that may present a danger to their health.

This is of particular importance in the case of vehicles with electric traction, which are equipped with one or more battery packs that can be connected to the power grid to accumulate the energy required to provide power for engine operation.

In this context, failures or damage may occur to the devices, cables in particular, used to connect the vehicle to the power grid.

When such an eventuality occurs, a situation may arise in which the vehicle frame is no longer correctly electrically insulated from the circuitry and components that connect the grid to those elements of the vehicle to be powered/charged, and consequently an electrical potential builds up on it in relation to a zero potential ground.

If a user subsequently touches the frame, the circuit between the latter and the earth is then closed and an electric current is discharged through their body with the risk of causing extensive and potentially irreversible harm.

In this context, it is clear how the possibility of monitoring the potential of the vehicle frame, especially when connected to the power grid, is of particular and significant importance, as it allows the user to be immediately alerted to the onset of a potentially dangerous situation.

However, not all power grids have the same characteristics in terms of potentials, frequencies and phases, and even the same grid can be subject to fluctuations in its characteristic values that, however slight, can still have a significant impact on its performance and on the characteristics of the voltage and current supplied.

Therefore, even the monitoring of the voltage potential that could be accumulated on the frame is extremely complex, since to date there are no known methodologies capable of providing, in a manner that is rapid, precise and above all independent of the characteristics of the grid, indications of this potential and information that allow the accurate discrimination of the actual hazardousness of situations that may occur.

In the automotive sector, there is therefore a strong need to develop new solutions capable of providing a mechanism for monitoring potential hazardous situations that may arise when, for whatever reason, a vehicle is connected to a power grid.

In this context, the technical task at the basis of this invention is to propose a monitoring method that overcomes at least some of the drawbacks of the known technique mentioned above.

In particular, one purpose of this invention is to provide a monitoring method capable of quickly, accurately and precisely determining the voltage value on a vehicle frame with respect to an earthing in order to then be able to alert the user of potentially hazardous situations when this voltage value has certain characteristics.

The specified technical task and the specified purposes are substantially achieved with a monitoring method comprising the technical features set forth in one or more of the appended claims.

According to this invention, a method for monitoring a voltage value is shown.

In particular, the method described herein can be implemented for monitoring a voltage value on a vehicle frame connected to an electrical grid.

The method is performed by acquiring a first signal representative of a voltage value between a first terminal connected to a first node of the power grid and the vehicle frame.

A second signal representing a voltage value between a second terminal connected to a second node of the power grid and the frame is also acquired.

The first signal is filtered in a filtering band comprising and preferably centred on the grid frequency generating:
a low frequency component comprising contributions to the first signal in a frequency range below the grid frequency;
a grid frequency component comprising the contributions to the first signal in a frequency range around the grid frequency;
a high-frequency component comprising contributions to the first signal in a frequency range above the grid frequency.

The second signal is also filtered, independently of the first signal, in the same manner, generating corresponding components.

In particular, the following are generated:
a low-frequency component comprising the contributions to the second signal in a frequency range below the grid frequency;
a grid frequency component comprising the contributions to the second signal in a frequency range around the grid frequency;
a high-frequency component comprising the contributions to the second signal in a frequency range above the grid frequency.

The low-frequency components, the components at the grid frequency and the high-frequency components are analysed to check whether or not the respective representative values associated with them exceed corresponding predetermined threshold values.

Depending on the result of this verification step, a warning signal is generated.

Advantageously, the procedure outlined here provides a particularly accurate and precise way of assessing the potential between the vehicle frame and an earthing.

This is achieved, in particular, by separating the measured voltage values into components belonging to distinct frequency ranges, whereby the components at the grid frequency (thus influenced by the behaviour of the power grid itself) can be assessed and analysed separately from those at lower and higher frequencies, thus enabling them to be analysed taking into account the specificities of the individual contributions at the various frequencies of interest.

The dependent claims, incorporated herein for reference, correspond to different embodiments of the invention.

Further features and advantages of this invention will become clearer from the indicative, and therefore non-limiting, description of a preferred, but not exclusive, embodiment of a monitoring method, as illustrated in the accompanying drawings in which:

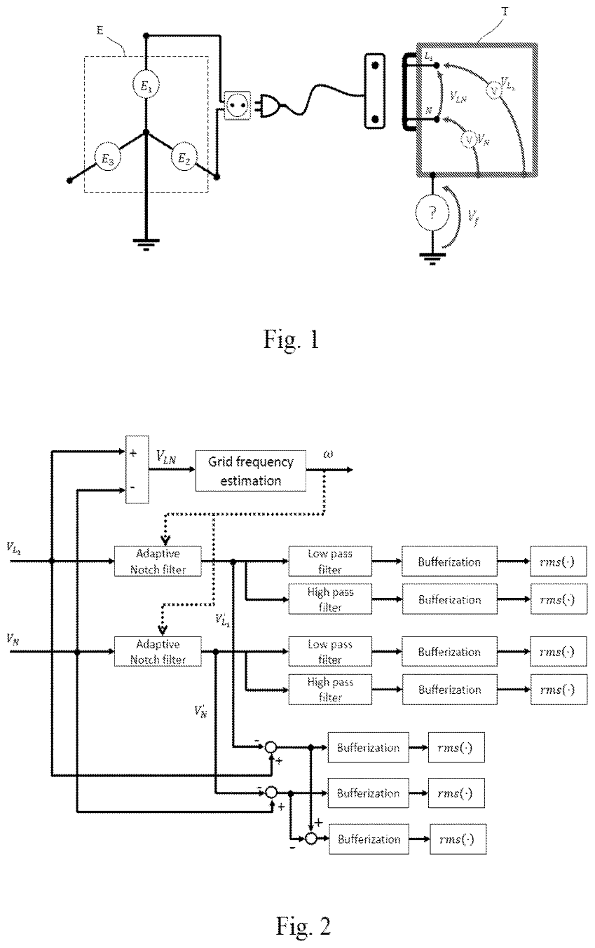

FIG. 1 shows in general terms a circuit diagram of a possible situation for implementing the method in which certain parameters of interest are identified;

FIG. 2 shows a block diagram illustrating the logical structure of the method according to this invention, with particular emphasis on how the signals of interest are processed;

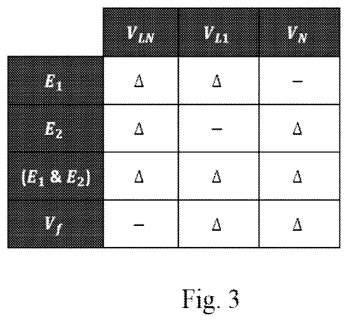

FIG. 3 illustrates the operating logic according to which a warning signal is generated for the user in a particular operation of the method.

As indicated, the method according to this invention makes it possible to monitor a voltage value and therefore the electrical potential (indicated in the figures as the risk potential Vf) accumulated on the frame T of a vehicle with respect to an earthing, when the latter is connected to a power grid E.

Such a situation may occur, for example, if one considers a vehicle with an electrically powered traction that requires for its proper functioning the presence of a battery pack that can be recharged by connecting it via appropriate devices to the power grid E.

If the connection between the power grid E and the vehicle, in particular between the power grid E and vehicle components that need to be powered/recharged, is damaged or defective, a short-circuit may be generated that electrically connects the vehicle frame T with the power grid E.

If the potential accumulated by the frame T were to exceed predetermined limit values, this could pose a danger to anyone coming into contact with the frame T, creating considerable risks to their health.

Operationally, the monitoring is performed by measuring the voltage values present between the terminals that connect the vehicle with the nodes of the power grid E and its frame T, processing them to extract representative values to be compared with appropriate threshold values and generating a warning signal if such a comparison leads to identifying a hazardous situation for the user's health.

In detail, the method is performed by acquiring a first signal V_{L1} representative of a voltage value between a first terminal L1 connected to a first node E1 of the power grid E and the vehicle frame T.

In other words, the first signal V_{L1} identifies the electrical potential established between the vehicle frame T and the terminal L1 through which the vehicle is connected to a first node E1, for example a first phase, of the power grid E.

Similarly, a second signal V_{N} representing a voltage value between a second terminal N connected to a second node E2 of the power grid E and the frame T is also acquired.

In other words, the second signal V_{N} identifies the electrical potential established between the vehicle frame T and the terminal N by means of which the vehicle is connected to a second node E2 of the power grid E, in which there may be an additional phase (as illustrated in FIG. 1) or even a neutral node with zero potential.

The first and second signal V_{L1}, V_{N} are then frequency filtered independently of each other in such a way that they are divided into respective separate components belonging to contiguous frequency ranges, which will be processed, analysed and evaluated independently of each other.

In more detail, the first signal V_{L1} and the second signal V_{N} are filtered in a filtering band comprising and preferably centred on the grid frequency ω of the power grid E.

This specific solution makes it possible to generate a first filtered signal and a second filtered signal each comprising:
a low frequency component
a component at the grid frequency ω;
a component at another frequency.

Specifically, the low-frequency component comprises contributions to the first or second signal V_{L1}, V_{N} belonging to a frequency range below the grid frequency ω.

On the other hand, the grid frequency component w comprises contributions to the first or second signal V_{L1}, V_{N} belonging to a frequency range around the network frequency ω.

Finally, the high-frequency component comprises the contributions to the first or second signal V_{L1}, V_{N} belonging to a frequency range above the grid frequency ω.

In other words, the first and second signals V_{L1}, V_{N} are filtered in such a way as to divide and isolate the components of those signals that have a frequency comparable with the grid frequency ω, and that will therefore be affected by the fluctuations and specific characteristics of the operating parameters of the power grid E, with respect to the components that have a lower frequency (identified as low-frequency components) and with respect to the components having a higher frequency (identified as high-frequency components).

Therefore, both the first filtered signal and the second filtered signal comprise three respective components that can be processed and evaluated independently to determine the presence of possible hazardous situations.

This feature is essential because different frequency components can present different degrees of hazardousness to the user's health and, in addition, the component at the grid frequency ω is influenced by the specific characteristics and behaviour over time of the power grid E and therefore it is advantageous to isolate it and consider it separate from the other components.

These components, i.e. the low-frequency components, the high-frequency components and the components at the grid frequency ω of the first filtered signal and the second filtered signal are analysed in order to ascertain whether or not a representative value associated with these components exceeds respective predetermined threshold values.

As indicated, components with different frequencies present different degrees of hazardousness, and therefore the division of the first signal V_{L1} and the second signal V_{N} into separate portions allows each of them to be evaluated according to its specific degree of hazardousness.

This avoids either failing to identify a hazardous situation (because a general threshold has been set that is adequate for some frequencies but is too high for others) or generating unnecessary warning signals when in reality there is no risk for the user (because a general threshold has been set that is adequate for some frequencies but is too low for others).

Therefore, the threshold values associated with the respective components may differ from each other and in particular be lower for those components at frequencies such that even minimal potential values can create risks, and higher for those components at frequencies such that even higher voltage values do not in fact pose any particular risk to the user's health.

If necessary, it is also possible to set different threshold values for the components of the first filtered signal and those of the second filtered signal, or to set the same threshold values for the components of the two separate signals belonging to the same frequency range.

Operationally, the representative values of the low-frequency components and the high-frequency components (i.e. the components that are not influenced by the behaviour of the power grid E) can be directly compared with the respective threshold values.

On the contrary, in order to adequately take into account the possible influence of the power grid E and its characteristics, it is advantageous to evaluate the components at the grid frequency ω by applying an additional analysis step.

In particular, the analysis of the components at the grid frequency ω can be performed by generating a differential signal V_{LN} equal to the difference between the component at the grid frequency ω of the first filtered signal and the component at the grid frequency ω of the second filtered signal V_{N}.

It is noted that in the case where the second terminal is connected to a neutral node then the differential signal V_{LN} will be substantially equal to the first filtered signal thus allowing a simplification of the analysis procedure outlined below.

This differential signal V_{LN} actually represents the grid frequency component w of the voltage between the first and the second terminal L1, N, thus being entirely dependent on the voltage variations of the first and the second node E1, E2 of the power grid E and being at the same time independent from the risk potential Vf e and its variations.

In this specific context, the warning signal is generated if:
at least one of the representative value associated with the component at grid frequency ω of the first filtered signal and the representative value associated with the component at the grid frequency ω of the second filtered signal exceed a respective first threshold value,
simultaneously the representative value associated with the differential signal V_{LN} is equal to or less than a second threshold value.

If the second terminal is connected to a neutral node, it will be sufficient to monitor only the representative value associated with the component at the grid frequency ω of the first filtered signal.

The decision-making process leading to the generation of the warning signal in this context is schematically depicted in FIG. 3, where it can be observed how variations in the voltage values of nodes E1 and E2 alone cause a corresponding variation (indicated in the table by the symbol A) in the representative values of V_{LN} and V_{L1} and V_{N} respectively.

Similarly, a simultaneous change in both E1 and E2 causes a change in the representative values of the first signal V_{L1}, the second signal V_{N} and the differential signal V_{LN}.

Therefore, variations at nodes E1 and E2 that have no influence on the value of the risk potential Vf also necessarily cause a variation in the value of V_{LN}

On the contrary, a variation in the value of the risk potential Vf (and therefore the occurrence of a potential hazardous situation) is identified by variations in the representative values of the first signal V_{L1} or the second signal V_{N} alone, without any variations in the representative value of the differential signal V_{LN}, whose value as defined above is not influenced (and does not influence) the value of the risk potential Vf.

It can be seen that in the table shown in FIG. 3 there is only one row for evaluating the effects of the variations of the risk potential on the representative values of the signals V_{L1}, V_{N} and V_{LN} because if a situation occurs in which the risk potential Vf varies and at the same time there are no variations (or no significant variations) in the representative value of the differential signal V_{LN} then both the first and the second signal V_{L1}, V_{N} must be changing.

Also in the case in which the second terminal is connected with a neutral node, it can be observed that any variations in the first signal V_{L1} such as to cause a variation in the risk potential Vf also generate a corresponding variation in the second signal V_{N}, since in this context the value of the risk potential Vf would be of equal modulus and the opposite sign with respect to the value of the second signal V_{N}.

Operationally, therefore, when the value of the differential signal V_{LN} does not change, it is sufficient to identify that at least one of the values of the first signal V_{L1} and the second signal V_{N} exceeds the respective threshold value in order to identify a risk situation.

The procedure outlined above defines a particularly accurate way of identifying risk situations, since the warning signal is only generated when the variations on the first and second signal V_{L1}, V_{N} are actually such as to modify the risk potential Vf, avoiding the generation of false alarms when instead such fluctuations are ‘absorbed’ by the differential signal V_{LN} and do not actually have any impact on the risk potential Vf.

From a practical point of view, the value, specifically the representative value, of each component to be taken into consideration for comparison with the respective threshold can be selected as equal to the modulus of the difference between an effective value (root-mean-square, rms) of that component and a respective base value.

In more detail, the base value for the low-frequency and high-frequency components can be set to 0 or alternatively to a predetermined voltage value.

On the other hand, for the grid frequency ω component, the base value corresponds to an initial effective value of this component, i.e. the effective value calculated at the moment the vehicle is connected to the power grid E.

Operationally, these effective values are evaluated over a predefined time interval that can be selected by varying the specific characteristics of an appropriate buffer.

As illustrated in FIG. 2, a respective buffer is applied to each component of each signal, and it is therefore also possible to set different time intervals for the evaluation of the effective values of individual components.

In general, the representative value identifies the variations of the effective value of the component under analysis with respect to its initial/base value, which for the component at the grid frequency ω is calculated/determined when the vehicle is connected to the power grid E and when the connection between the two is considered to be correctly functioning.

This representative value can then be expressed using the formula:

$$Δ V x , y = \vert rms ( {v}_{x , y nominal} - rms ( {V}_{x , y} ) \vert$$

wherein:
ΔVx identifies the representative value of the component at the grid frequency ω relative to the signal x (where x can therefore be L1, N or LN);
rms (Vₓ nominal) identifies the base value, i.e. the effective value the component at the grid frequency ω of the signal x measured when the vehicle is connected to the power grid (E);
rms (Vₓ) identifies the measured effective value for the component at the grid frequency ω the signal x.

If the analysis process identified above (which will be explored in greater detail below with reference to specific possible embodiments) leads to the identification of an exceeding of the respective threshold values by the representative values of the components identified for the respective signals, it is possible to generate a warning signal identifying a hazardous situation for the user.

In accordance with a first aspect, such a warning signal is configured to interrupt an electrical power transfer between the vehicle and the power grid E.

In other words, the warning signal is configured to decouple/disconnect the vehicle (hence the frame T) from the power grid E by interrupting the electrical connection present between the two.

Alternatively or additionally, the warning signal is configured to activate an optical signal (e.g. a warning light) and/or acoustic signal capable of promptly alerting the user to the risk situation so that the latter is warned of the need not to make contact with the vehicle frame T.

According to a possible preferred embodiment, the filtering phase of the first and second signals is performed by independently processing the first signal V_{L1} and the second signal V_{N} by means of a respective band-stop filter (notch filter, preferably of the adaptive type as illustrated in FIG. 2), which has a resonance frequency equal to the network frequency ω.

In this manner, a first filtering signal V′_{L1} and a second filtering signal V′_{N} are generated, and by subtracting these first and second filtering signals V′_{L1}, V′_{N} respectively from the first and second filtering signals V_{L1}, V_{N}, the grid frequency ω components of the first and second filtered signals are generated.

Also in the specific embodiment just outlined, the low-frequency components can be generated by independently filtering the first filtering signal V′_{L1} and the second filtering signal V′_{N} by means of a respective low-pass filter.

Similarly, the high-frequency components can be generated by independently filtering the first filtering signal V′_{L1} and the second filtering signal V′_{N} by means of a high-pass filter.

In other words, the band-stop filter removes from the first and second signal V_{L1}, V_{N} the contribution of the voltages at the grid frequency ω thus generating respective filtering signals V′_{L1}, V′_{N} that can, in turn, be further divided to separate the low-frequency and high-frequency components that are in no way dependent on the specific behaviour of the power grid E.

These components represent a directly measurable indicator of the value of the hazard potential Vf at low and high frequencies (i.e. for the purposes of this invention at frequencies lower and higher than the grid frequency ω).

In this context, a cut-off frequency of the low-pass filter can be selected equal to a lower cut-off frequency of the band-stop filter and a cut-off frequency of the high-pass filter can be selected equal to a higher cut-off frequency of the band-stop filter.

In this way, the first and second filtered signals are divided into three contiguous frequency ranges and it is possible to ensure that all components contributing to the overall value (and thus contributing to the value of the risk potential Vf) are appropriately evaluated.

Alternatively to the above, it is also possible to use a different filtering procedure by implementing one or more filters of a different nature or, in any case, characterised by appropriate and specific transfer functions, as long as they are capable of leading to the separation and discrimination of the components of the filtered signals into the three frequency ranges of interest for the analysis leading to the generation of the warning signal.

Advantageously, the method of this invention may further comprise a step of estimating the grid frequency ω.

In this way, when the vehicle is connected to the power grid E, it is possible to identify the specific grid frequency ω in such a way that it is possible to accurately set the frequency ranges according to which the division of the first and second signal V_{L1}, V_{N} is to be made.

This step thus makes it possible to make the method that is the subject of this invention easily adaptable to operate on power grids E that have different characteristics.

In detail, the estimation process is carried out by sampling the value of the differential signal V_{LN} with a predefined sampling frequency and dividing this sampling frequency by a counter equal to the number of samplings elapsed between two successive time intervals in which the differential signal V_{LN} has passed from a negative value to a positive value.

In other words, the grid frequency ω is operationally equal to the frequency of the differential signal V_{LN} and, therefore, by estimating the frequency of the latter using the procedure outlined above, it is possible to identify the grid frequency ω.

Advantageously, this invention achieves the proposed purposes by overcoming the drawbacks complained of in the prior art by providing the user with a monitoring method that enables the detection the occurrence of potential problems and risks related to the accumulation of an electrical potential on the vehicle frame T on any power grid E.

1. A method for monitoring a voltage value on a vehicle frame when connected to a power grid, said method comprising the steps of:
acquiring a first signal representing a voltage value between a first terminal connected to a first node of the power grid and the vehicle frame;
acquiring a second signal representing a voltage value between a second terminal connected to a second node of the power grid and the frame;
independently filtering the first signal and the second signal in a filtering band comprising and preferably centred on a grid frequency of said power grid, so as to generate a first filtered signal and a second filtered signal, respectively, each comprising:
a low frequency component comprising the contributions to the first or second signals in a frequency range below the grid frequency;
a component at the grid frequency comprising the contributions to the first or second signal in a frequency range around the network frequency;
a high frequency component comprising the contributions to the first or second signal in a frequency range above the grid frequency;
analysing the low frequency components, the components at the working frequency and the high frequency components to check whether a representative value associated with said components exceeds a respective predetermined threshold value;
generating a warning signal in the event of a positive check.

2. The method according to claim 1, wherein the step of analysing the components at the grid frequency is performed by generating a differential signal equal to the difference between the component at the grid frequency of the first filtered signal and the component at the grid frequency of the second filtered signal; said warning signal being generated if:
at least one between the representative value associated with the component at the grid frequency of the first filtered signal and the representative value associated with the component at the grid frequency of the second filtered signal exceeds a respective first threshold value; and
at the same time, the representative value associated with the differential signal is equal to or less than a second threshold value.

3. The method according to claim 1, wherein the representative value of each component is equal to the modulus of a difference between an effective value of said component and a respective base value.

4. The method according to claim 3, wherein each base value for the high frequency component and for the low frequency component is 0 and/or for the component at the grid frequency corresponds to an initial effective value of said component at the grid frequency, said initial effective value being calculated when the vehicle is connected to the electrical grid.

5. The method according to claim 1, wherein the step of filtering the first and second signals is performed by independently processing the first signal and the second signal by means of a respective band-stop filter having a resonance frequency equal to the grid frequency, so as to generate a first filtering signal and a second filtering signal, respectively, and subtracting said first and second filtering signals from the first and second signals, respectively, generating the components at the grid frequency of the first and second filtered signals.

6. The method according to claim 5, wherein the low frequency components are generated by independently filtering the first filtering signal and the second filtering signal by means of a low-pass filter.

7. The method according to claim 5, wherein the high frequency components are generated by independently filtering the first filtering signal and the second filtering signal by means of a high-pass filter.

8. The method according to claim 6, wherein a cut-off frequency of the low-pass filter is equal to a lower cut-off frequency of the band-stop filter, and a cut-off frequency of the high-pass filter is equal to a higher cut-off frequency of the band-stop filter.

9. The method according to claim 1, wherein the warning signal is configured to suspend a transfer of electrical power between the vehicle and the power grid.

10. The method according to claim 2, comprising a step of assessing the grid frequency, said assessment step being performed by sampling the value of the differential signal with a predefined sampling frequency and dividing this sampling frequency by a counter equal to the number of samplings between two successive time intervals in which the differential signal has passed from a negative value to a positive value.
